(19) United States
(12) Patent Application Publication
(10) Pub. No.: US 2004/0160689 A1
(43) Pub. Date: Aug. 19, 2004

(54) All-purpose motor screen

(75) Inventor: Chien-Yuan Chen, (US)

Correspondence Address: TROXELL LAW OFFICE PLLC, 5205 LEESBURG PIKE, SUITE 1404, FALLS CHURCH, VA, 22041, US

(73) Assignee: Power Data Communication Co., Ltd.

(21) Appl. No.: 10/366,329

(22) Filed: Feb. 14, 2003

(51) Int. Cl. G03F 5/00

(52) U.S. Cl. 359/893; 345/1.1

(57) ABSTRACT

The present invention provides an all-purpose motor screen. The screen is a removable liquid crystal screen. The screen cooperate outer drive module having drive circuit and battery device, and by changing drive module of various drive circuit to make the screen has various purposes, and can be driven by drive screen display image.

### BACKGROUND OF THE INVENTION

1. Field of the Invention

The present invention provides an all-purpose motor screen, especially provides an expansion motor screen having digital camera, digital video camera, MP3 broadcaster.

2. Description of Related Art

A well-known technique motor screen, as shown in FIG. 1, most of the screens 10 are liquid crystal screen, the screen 10 have a socket 11 for inserting into receiver 13, the corresponding parts of socket 11 and receiver 13 have hole 111 and flexible hook 131, the receiver 13 is pivoted connected to a body 12, the body 12 is connected to a bed 14 by a rivet 121, the bed 14 can be hold between mainframe body 15 and outer body 16, the socket 11 electrically connects with receiver 13. After socket 11 is inserted into receiver 13, the receiver 13 can introduce power to make the screen 10 display image. Because the volume of screen 10 is small and easily be stolen, so the screen 10 is removable, when driver gets off he may remove the screen 10 and carries it with him, when gets on he may assemble screen 10 again. The screen 10 has no other functions except used in motor so has small practicability.

### SUMMARY OF THE INVENTION

Whereas above-mentioned disadvantages, the main object of the present invention is to provide an all-purpose motor screen, which takes advantage of the property of small volume and easily-carry to connect motor screen to drive module and battery module to make itself has the factions of digital camera, digital video camera, MP3 broadcaster.

### BRIED DESCRIPTION OF THE DRAWINGS

FIG. 1 is a structure sketchy view of a well-known motor screen;

FIG. 2A and FIG. 2B are operating sketchy views of the drive module inserting into the screen of the present invention;

FIG. 3 is a sketchy view of another embodiment of the drive module inserting into the screen of the present invention

FIG. 4 is a perspective view of another preferential embodiment of drive module of the present invention;

FIG. 5 is a block diagram of circuit of the present invention.

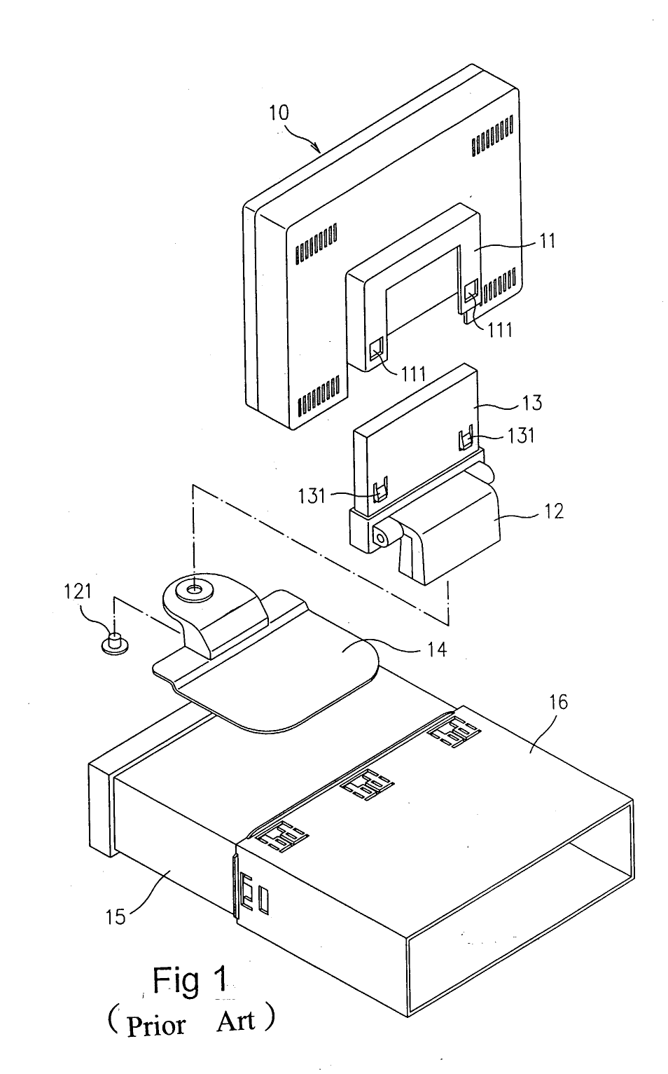

### DESCRIPTION OF SYMBOLS OF THE DRAWINGS

10 screen

11 socket

111 hole

12 body

121 rivet

13 receiver

131 flexible hook

14 bed

15 mainframe body

16 outer body

20 screen

21 socket

211 hole

22 body

221 rivet

23 receiver

231 flexible hook

24 bed

25 mainframe body

26 outer body

27 groove

30 drive module

31 socket

32 drive socket

33 battery device

34 blue-tooth device

35 central process unit

36 input key

37 output device

38 microphone

40 drive module

41 flexible hook

50 digital camera memory card

60 storage memory card

70 receive device

### DETAILED DESCRIPTION OF THE PREFERRED EMBODIMENT

The present invention will now be described in further detail hereinafter, with reference to the accompanying drawings.

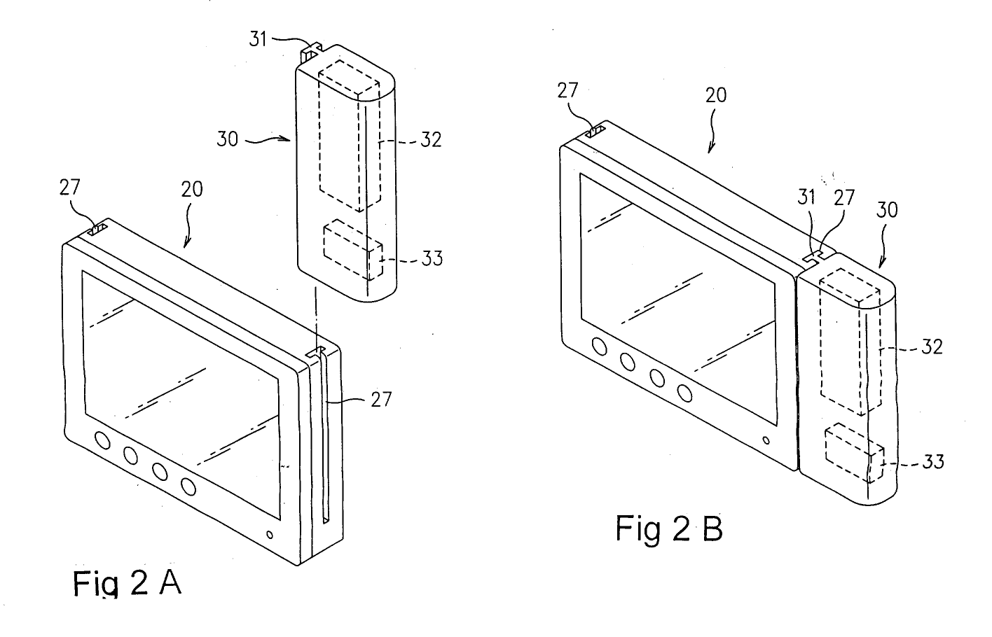

As shown in FIG. 2, an all-purpose motor screen according to the present invention, the screen 20 has a socket 21 for inserting into receiver 23, the corresponding parts of socket 21 and receiver 23 have hole 211 and flexible hook 231. The receiver 23 is pivoted connected to a body 22, the body 22 is connected to a bed 24 by a rivet 221, the bed 24 can be held between mainframe body 25 and outer body 26. The socket 21 is electrically connected with receiver 23 (not shown). After inserting socket 21 into receiver 23, flexible hook 231 will be held in the hole 211 that can avoid socket 21 separate from receiver 23, at the same time, body 22 can introduce drive circuit into screen 20 to enable screen 22 display image. When driver gets off he may remove the screen 20 and carries it with him to avoid screen 20 be stolen.

As shown in FIG. 2A and FIG. 2B, the present invention takes advantage of the character of screen 20: removable, small volume, easy to carry, outer driver module 30 cooperates with screen 20. As shown in FIGS, the screen 20 has groove 27, the drive module 30 has socket 31, and groove 27 is electrical connected with socket 31 (not shown), there are many models of electrical connecting, such as conductive flexible piece, touch point, those are well-known technique and will not be described here. After inserting socket 31 into groove 27, drive module 30 can be connected with screen 20, drive module 30 drive screen 20 to display image. The drive module 30 may be digital camera, digital video camera or MP3 broadcaster module. The drive module 30 has drive circuit 32 and battery device 33 in the inertial. If the drive module 30 is a digital camera module, which must has drive circuit of digital camera, adjust switch and so on, after screen 20 be connected with drive module 30, the drive module 30 will be used as digital camera. Because the drive module 30 has battery device 33, so the additional power will not be needed, that is easy to carry and convenient for use in open air. The battery device 33 may be chargeable storage battery that is economical and environment-protect. Screen 20 will has various purposes when use various drive modules. At the same time, when drive module 30 be inserted into, the screen 20 will be insert into receiver 23 of body 22 to transfer information with mainframe body 25.

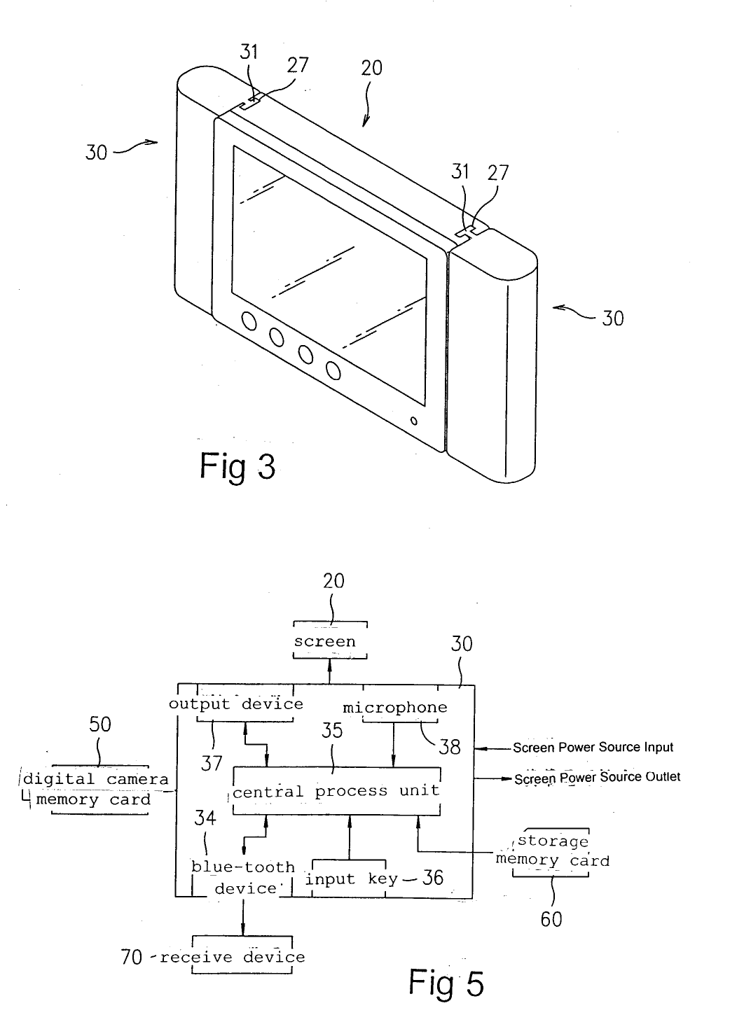

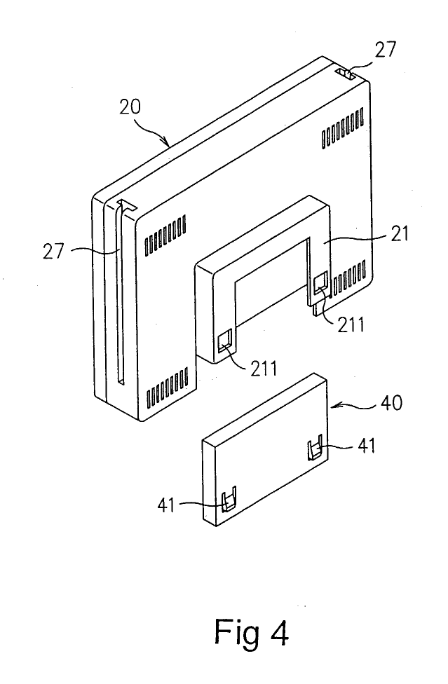

And, screen 20 may has a plurality of drive modules 30, as shown in FIG. 3, screen 20 may have drive modules 30 on both sides of the screen 20 at the same time, of course, drive module 30 may be set on the bottom or other position of screen 20, and the link style of screen 20 with drive module 30 is also not confined in said the link style of socket 31 with groove 27 and may be hold or hook connecting, or as shown in FIG. 4, the outline of drive module 40 is same as the outline of receiver 23 of said body 22. The drive module 40 has flexible hook 41 corresponding to hole 211 of socket 21. Drive module 40 may be inserted into socket 21 of screen 20 and flexible hook 41 may be hold in the hole 211 to avoid drive module 40 separate from socket 21. Although the design room is small and the difficult of design is great, and after setting drive module 40 the screen 20 will not be inserting into the receiver 23 of body 22, but the design has the advantage of not increasing the volume of screen 20.

As shown in FIG. 5, the block diagram of the present invention, in which, the drive module 30 comprises: blue-tooth module 34, central process unit 35, input key 36, output device 37, microphone 38 and so on. Said drive module 30 is used for outer receive device transferring signal. Central process unit 35 drives screen 20 display image, output device 37 outputs sound; said drive module 30 has memory card plugging plot for digital camera memory card 50 or storage memory card 60 inserting into (not shown), drive module 30 processes digital camera memory card 50 or storages information of memory card 60, central process unit 35 drives screen 20 display image, output device 37 outputs sound, microphone 38 inputs sound, sound processed by central process unit 35 will be transfer to storage memory card 60 or receive device 70.

To sum up, after the present invention added motor screen to drive module, motor screen will be enabled new purposes, and consumers only need set module needed. While the present invention has been described above is only an embodiment of the present invention that will not confine the scope of the present invention, and various modifications and alterations may be made without departing from the scope of the invention will be regard as other embodiments of the present invention.

What is claimed is:

1. An all-purpose motor screen, the screen having a socket for inserting into a receiver of body and is electrical connected to receiver, wherein,
Said screen has outer drive module, the drive module is removable connected and electrically connected with screen; screen has various purposes by removing or installing drive module; install drive module to drive screen display image;

2. The all-purpose motor screen according to claim 1, wherein, the link style of drive module and screen is removable:
said screen has groove, said drive module has socket, said groove is electrically connected with said socket, after socket be inserted into groove, drives module may be connected with screen, drive module drives screen to display image.

3. The all-purpose motor screen according to claim 1, wherein said drive module is inserted in said socket of screen.

4. The all-purpose motor screen according to claim 1, wherein said screen is liquid crystal screen.

5. The all-purpose motor screen according to claim 1, wherein said drive module is a digital camera module.

6. The all-purpose motor screen according to claim 1, wherein said drive module is a digital video camera module.

7. The all-purpose motor screen according to claim 1, wherein said drive module is a MP3 broadcaster module.

8. The all-purpose motor screen according to claim 1, wherein said drive module comprises battery module.

9. The all-purpose motor screen according to claim 1, wherein said drive module comprises:
blue-tooth module for providing receive device to transfer information each other;
central process unit for processing received information;
input key;
output device for providing sound output processed by central process unit;
microphone for inputting sound, the inputting sound then be processed into electric file or sign.
